(19) United States
(12) Patent Application Publication
(10) Pub. No.: US 2008/0277678 A1
(43) Pub. Date: Nov. 13, 2008

(54) Light emitting device and method for making the same

(75) Inventors: Yu-Chu Li, Taichung City (TW); Chiung-Chi Tsai, Taichung City (TW); Tzong-Liang Tsai, Hsinchu City (TW); Su-Hui Lin, Taichung City (TW)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Huga Optotech Inc., Taichung (TW)

(21) Appl. No.: 11/801,155

(22) Filed: May 8, 2007

(51) Int. Cl. H01L 29/22; H01L 21/00; H01L 27/15

(52) U.S. Cl. 257/94; 257/79; 438/22; 438/47; 257/E27.12; 257/E29.094; 257/E21.001

(57) ABSTRACT

A method for making a light emitting device includes: forming a multi-layer structure on a substrate; forming a patterned mask material on one side of the multi-layer structure such that the patterned mask material covers an etch region of the multi-layer structure; forming a roughened layer on the multi-layer structure; removing the patterned mask material from the multi-layer structure so as to expose the etch region of the multi-layer structure; forming an etch mask material on the roughened layer; dry etching the multi-layer structure at the exposed etch region so as to define an electrode-forming region on the first semiconductor layer that corresponds to the etch region of the multi-layer structure; and forming an electrode on the electrode-forming region of the first semiconductor layer.

### BACKGROUND OF THE INVENTION

1. Field of the Invention

This invention relates to a method for making a light emitting device, more particularly to a method involving forming an electrode-forming region on a semiconductor layer of a light emitting device using dry etching techniques.

2. Description of the Related Art

FIG. 1 illustrates a conventional light emitting device 1 that includes a sapphire substrate 11, an epitaxial layered structure 12 formed on the sapphire substrate 11, a roughened layer 13 of a III-V material formed on the epitaxial layered structure 12, a transparent conductive layer 14 formed on the roughened layer 13, an n-type contact electrode 15, and a p-type contact electrode 16. The epitaxial layered structure 12 includes a first semiconductor layer 121 of a n-type GaN material, a second semiconductor layer 123 of a p-type GaN material, and an active layer 122 of an InGaN-based material that is sandwiched between the first and second semiconductor layers 121, 123. The light emitting device 1 is formed with an etched recess 17 extending along an edge thereof into the first semiconductor layer 121 and having a bottom side defined by an electrode-forming region 124 of the first semiconductor layer 121. The n-type contact electrode 15 is formed on the electrode-forming region 124 of the first semiconductor layer 121, while the p-type contact electrode 16 is formed on the transparent conductive layer 14.

FIG. 2A to 2C illustrate consecutive steps of a process for making the light emitting device 1. The process includes: forming the first semiconductor layer 121, the active layer 122 and the second semiconductor layer 123 in sequence on the sapphire substrate 11 (see FIG. 2A); forming the roughened layer 13 on the second semiconductor layer 123 (see FIG. 2A); forming the transparent conductive layer 14 on the roughened layer 123 (see FIG. 2A); dry etching the layered structure thus formed so as to form the etched recess 17 and to define the electrode-forming region 124 of the first semiconductor layer 121 (see FIG. 2B); forming the n-type contact electrode 15 on the electrode-forming region 124 of the first semiconductor layer 121 (see FIG. 2C); and forming the p-type contact electrode 16 on the transparent conductive layer 14 (see FIG. 2C).

By virtue of dry etching, the material of the layered structure thus formed is removed in a highly anisotropic manner, i.e., an essentially vertical etch profile is produced. As a consequence, since the dry etching starts from the transparent conductive layer 14 which has a roughened surface (i.e., recesses and protrusions are formed thereon) conforming to that of the roughened layer 13, undesired sidewall residuals, which may include a residual 122+ of the active layer 122 and a residual 123′ of the second semiconductor layer 123, are likely to form and remain on the electrode-forming region 124 of the first semiconductor layer 121. Hence, instead of being formed on the first semiconductor layer 121, the n-type contact electrode 15 is formed on the sidewall residuals, which can cause current leakage or short circuit for the light emitting device 1.

FIG. 3 illustrates a light emitting device 2 disclosed in U.S. Pat. No. 7,049,638. The light emitting device 2 includes a sapphire substrate 21, an epitaxial layered structure 22 formed on the sapphire substrate 21, a patterned buffer layer 23 of a cluster material (which may include a mixture of Si_{c}N_{d}, Mg_{g}Nₕ, and highly doped AlₖInₗGaₗ₋ₖ₋ₗN) formed on an etch region of the epitaxial layer structure 22, a roughened contact layer 24 formed on an extraction region of the epitaxial layered structure 22, a transparent conductive layer 25 formed on the roughened contact layer 24, an n-type contact electrode 26, and a p-type contact electrode 27 formed on an area of the roughened contact layer 24. The epitaxial layered structure 22 includes a buffer layer 221 of an AlInGaN material, a first semiconductor layer 222 of a n-type GaN material, an active layer 223 of an InGaN material, a second semiconductor layer 224 of a p-type semiconductor material, and a contact layer 225 of a p-type GaN material. The n-type contact electrode 26 is formed on an electrode-forming region 226 of the first semiconductor layer 222. An etched recess 227 is formed by dry etching techniques so as to define the electrode-forming region 226 of the first semiconductor layer 222. Similar to the previous light emitting device 1, the dry etching starts from the transparent conductive layer 25, which has a roughened surface similar to that of the roughened contact layer 24, thereby resulting in the formation of undesired sidewall residuals (not shown).

### SUMMARY OF THE INVENTION

The object of the present invention is to provide a method for making a light emitting device that can overcome the aforesaid drawbacks associated with the prior art.

According to one aspect of this invention, there is provided a method for making a light emitting device that comprises: (a) forming a multi-layer structure, which includes first and second semiconductor layers and an active layer disposed between the first and second semiconductor layers, on a substrate; (b) forming a patterned mask material on one side of the multi-layer structure that is opposite to the substrate so as to cover an etch region of the multi-layer structure; (c) forming a roughened layer on said one side of the multi-layer structure to cover an extraction region of the multi-layer structure; (d) removing the patterned mask material from the multi-layer structure so as to expose the etch region of the multi-layer structure; (e) forming an etch mask material on the roughened layer; (f) dry etching the multi-layer structure at the exposed etch region so as to form an etched recess extending through the second semiconductor layer and the active layer and into the first semiconductor layer and so as to define an electrode-forming region on the first semiconductor layer that corresponds to the etch region of the multi-layer structure; and (g) forming an electrode on the electrode-forming region of the first semiconductor layer.

According to another aspect of this invention, there is provided a light emitting device that comprises: a substrate; a multi-layer structure formed on the substrate and including first and second semiconductor layers and an active layer sandwiched between the first and second semiconductor layers, the multi-layer structure being formed with an etched recess that extends through the second semiconductor layer and the active layer and into the first semiconductor layer so as to define an electrode-forming region on the first semiconductor layer; a roughened layer formed on one side of the multi-layer structure that is opposite to the substrate, and formed with an electrode-receiving hole; a first electrode formed on the electrode-forming region of the first semiconductor layer; and a second electrode connected to said one side of the multi-layer structure and extending outwardly through the electrode-receiving hole. The electrode-forming region of the first semiconductor layer is defined by a process comprising forming a patterned mask material on said one side of the multi-layer structure so as to cover an etch region of the multi-layer structure that corresponds to the electrode-forming region of the first semiconductor layer, forming the roughened layer to cover an extraction region of the multi-layer structure, removing the patterned mask material from the multi-layer structure so as to expose the etch region of the multi-layer structure, forming an etch mask material on the roughened layer, and dry etching the multi-layer structure at the exposed etched region so as to form the etched recess and so as to define the electrode-forming region of the first semiconductor layer.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a fragmentary schematic view of a conventional light emitting device;

FIGS. 2A to 2C are schematic views to illustrate consecutive steps of a process for making the conventional light emitting device of FIG. 1;

FIG. 3 is a schematic partly sectional view of another conventional light emitting device;

FIG. 4 is a schematic view of the preferred embodiment of a light emitting device according to this invention;

FIGS. 5A to 5E are schematic views to illustrate consecutive steps of a method for making the light emitting device of the preferred embodiment according to this invention; and

FIG. 6 is an I-V characteristics diagram for comparison between the light emitting device of the preferred embodiment and a conventional light emitting device.

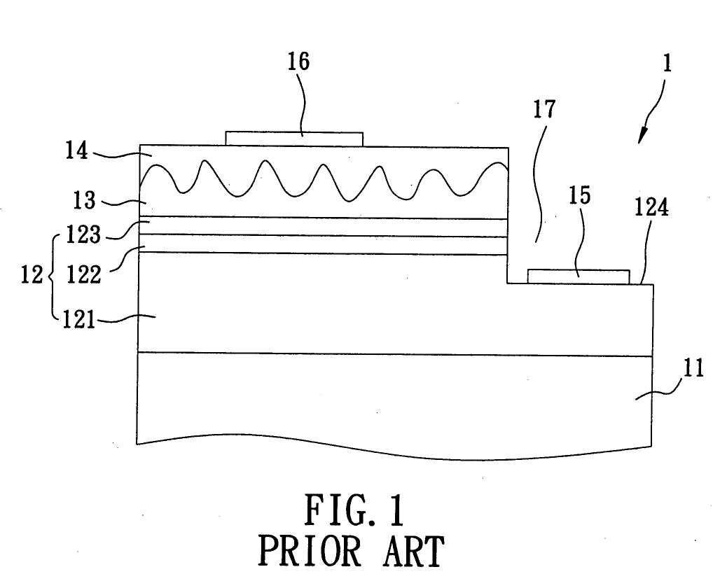

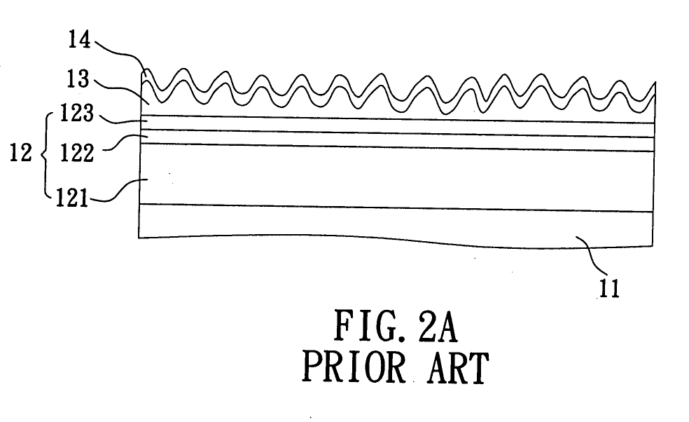

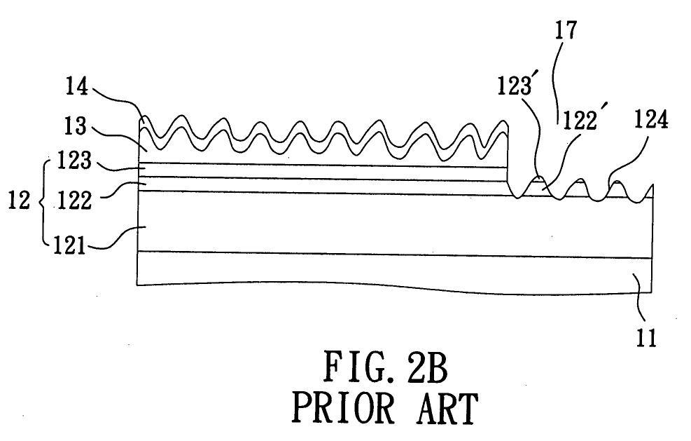

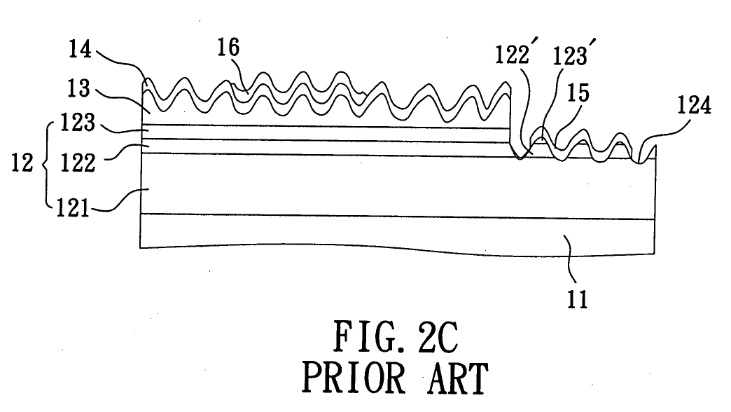

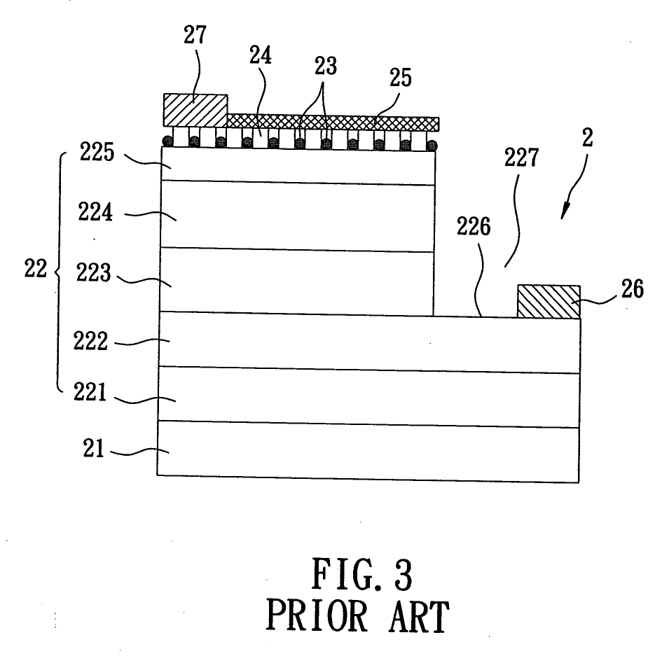

### DETAILED DESCRIPTION OF THE PREFERRED EMBODIMENT

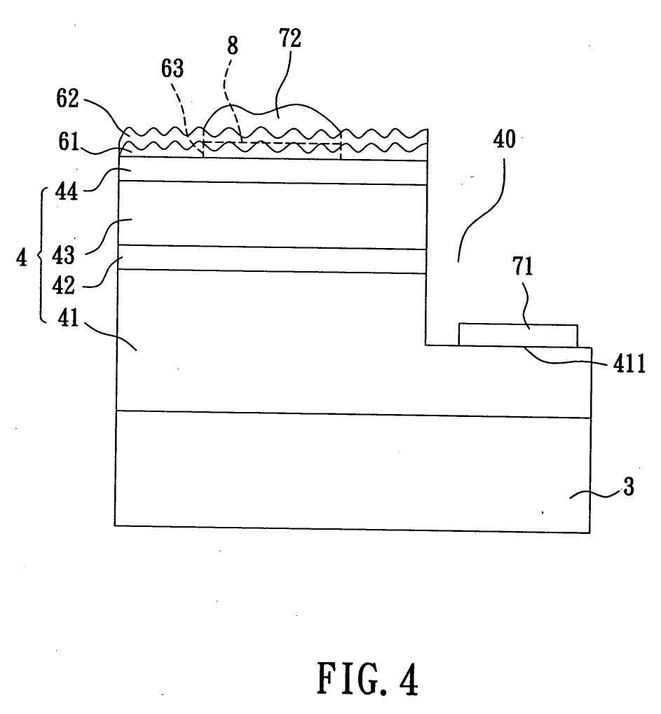

FIG. 4 illustrates the preferred embodiment of a light emitting device according to this invention. The light emitting device includes: a substrate 3; a multi-layer structure 4 formed on the substrate 3 and including first and second semiconductor layers 41, 43 and an active layer 42 sandwiched between the first and second semiconductor layers 41, 42, the multi-layer structure 4 being formed with an etched recess 40 that extends through the second semiconductor layer 43 and the active layer 42 and into the first semiconductor layer 41 so as to define an electrode-forming region 411 on the first semiconductor layer 41; a roughened layer 61 formed on one side of the multi-layer structure 4 that is opposite to the substrate 3, and formed with an electrode-receiving hole 63; a first electrode 71 formed on the electrode-forming region 411 of the first semiconductor layer 41; and a second electrode 72 connected to said one side of the multi-layer structure 4 and extending outwardly through the electrode-receiving hole 63.

In this embodiment, the multi-layer structure 4 further includes a transition layer 44 that is formed on the second semiconductor layer 43 and that is made from a II-V compound. The roughened layer 61 is made from a III-V compound, and is formed on the transition layer 44 so that growth of the roughened layer 61 on the transition layer 44 is conducted through heterogeneous nucleation mechanism. A transparent conductive layer 62 is made from indium tin oxide (ITO), and is formed on the roughened layer 61. Since the roughened layer 61 has a roughened surface, the transparent conductive layer 62 thus formed also has a roughened surface conforming to that of the roughened layer 61.

The second electrode 72 can be directly or indirectly connected to the transition layer 44. In this embodiment, a metal reflective layer 8 is formed on said one side of the multi-layer structure 4, i.e., on the transition layer 44, and extends into the electrode-receiving hole 63 in the roughened layer 61, and the second electrode 72 is formed on the metal reflective layer 8 and extends outwardly of the electrode-receiving hole 61 through the transparent conductive layer 62.

In this embodiment, the substrate 3 is made from sapphire, the first and second semiconductor layers 41, 43 are made from n-type and p-type GaN materials, respectively, and the active layer 42 is made from an InGaN-based material. Preferably, the transition layer 44 is made from a material having an energy gap ranging from 0.7 to 6.0 eV so as to enhance ohmic contact between the transparent conductive layer 62 and the second semiconductor layer 43.

Preferably, II group element of the II-V compound of the transition layer 44 is selected from the group consisting of Zn, Be, Mg, Ca, Sr, Ba, Ra, and combinations thereof, and V group element of the II-V compound of the transition layer 44 is selected from the group consisting of N, P, As, Sb, Bi, and combinations thereof. The transition layer 44 may be a binary, a ternary, or a quaternary compound. More preferably, the II-V compound of the transition layer 44 has a formula of MgₓN_{y}, in which 1<x<3, and 1<y<3.

Preferably, III group element of the III-V compound of the roughened layer 61 is selected from the group consisting of B, Al, Ga, In, Tl, and combinations thereof, and V group element of the III-V compound of the roughened layer 61 is selected from the group consisting of N, P, As, Sb, Bi, and combinations thereof.

Preferably, the metal reflective layer 8 is made from a metallic material selected from the group consisting of Ti, Al, Ag, Au, Cr, Pt, Cu, and combinations thereof.

In this embodiment, the transition layer 44 has a layer thickness ranging from 0.5 to 50 nm, the roughened layer 61 has a layer thickness ranging from 50 to 3000 nm, and the metal reflective layer 8 has a layer thickness ranging from 1 to 100 nm. When the layer thickness of the transition layer 44 is less than 0.5 nm, a continuous layer for the transition layer 44 cannot be achieved, and when the same is greater than 50 nm, ohmic contact between the second semiconductor layer 43 and the transparent conductive layer 62 is adversely affected. When the layer thickness of the roughened layer 61 is less than 50 nm, external light extraction thereby is significantly reduced, and when the same is greater than 3000 nm, external light extraction efficiency cannot be further enhanced. When the metal reflective layer 8 is less than 1 nm, reflectance of light is too low, and when the same is greater than 100 nm, adhesion strength of the metal reflective layer 8 on the transition layer 44 becomes poor and the metal reflective layer 9 tends to peel therefrom.

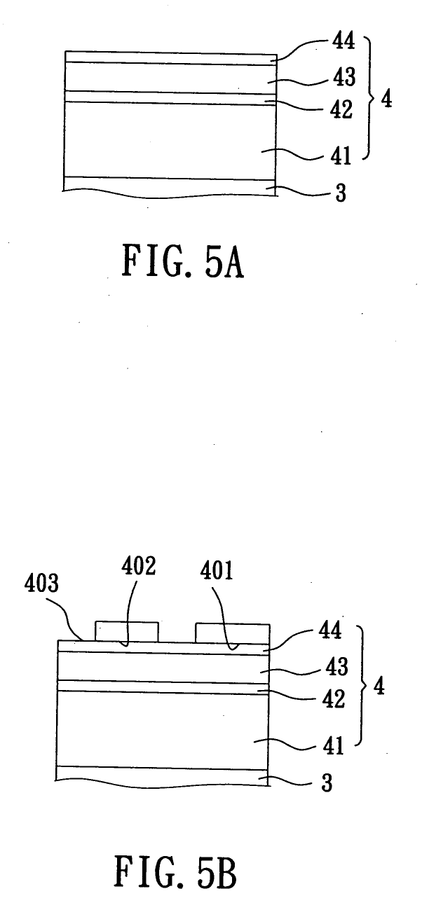

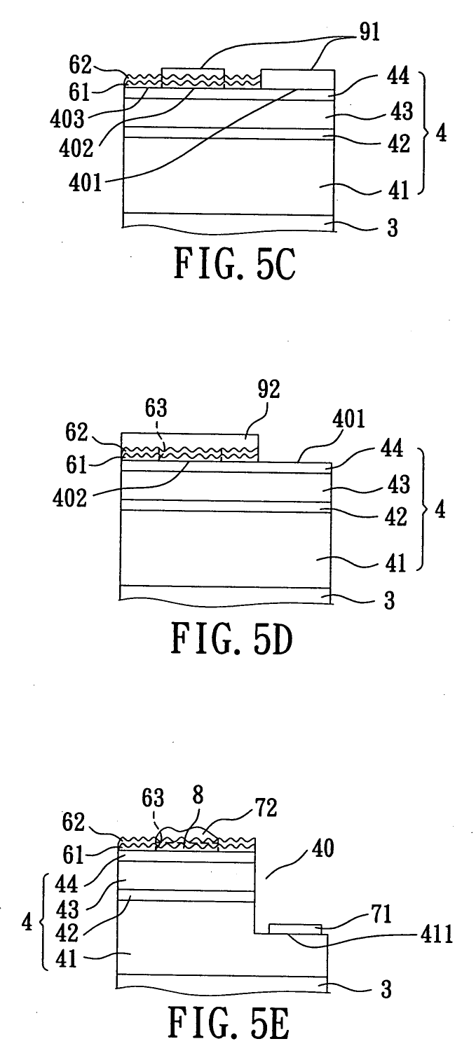

FIGS. 5A to 5E illustrate consecutive steps of a method for making the preferred embodiment of the light emitting device of this invention. The method includes the steps of: (a) forming the first semiconductor layer 41, the active layer 42, the second semiconductor layer 43 and the transition layer 44 of the multi-layer structure 4 in sequence on the substrate 3 (see FIG. 5A); (b) forming a patterned mask material 91 on one side of the multi-layer structure 4 that is opposite to the substrate 3 so as to cover an etch region 401 and a connecting region 402 of the multi-layer structure 4 (see FIG. 5B); (c) forming the roughened layer 61 on said one side of the multi-layer structure 4 to cover an extraction region 403 of the multi-layer structure 4 (see FIGS. 5B and 5C) such that the roughened layer 61 surrounds a portion of the patterned mask material 91 formed on the connecting region 402; (d) forming the transparent conductive layer 62 on the roughened layer 61 (see FIG. 5C) such that the transparent conductive layer 62 also surrounds the portion of the patterned mask material 91; (e) removing the patterned mask material 91 from the multi-layer structure 4 so as to expose the etch region 401 and the connecting region 402 of the multi-layer structure 4 (see FIG. 5D) and so as to form the electrode-receiving hole 63 in the roughened layer 61 and the transparent conductive layer 62; (f) forming an etch mask material 92 on the transparent conductive layer 62 (see FIG. 5D); (g) dry etching the multi-layer structure 4 at the exposed etch region 401 so as to form the etched recess 40 extending through the transition layer 44, the second semiconductor layer 43 and the active layer 42 and into the first semiconductor layer 41 and so as to define the electrode-forming region 411 on the first semiconductor layer 41 that corresponds to the etch region 401 of the multi-layer structure 4 (see 5E); (h) forming the first electrode 71 on the electrode-forming region 411 of the first semiconductor layer 41 (see FIG. 5E); (i) forming the metal reflective layer 8 on the connecting region 402 of the multi-layer structure 4 (see FIG. 5E) such that the metal reflective layer 8 extends into the electrode-receiving hole 63; and (j) forming the second electrode 72 on the metal reflective layer 8 (see FIG. 5E) such that the second electrode 72 extends outwardly of the electrode-receiving hole 63. Note that the transparent conductive layer 62 is not an essential element and can be omitted in other embodiments of this invention. The etch mask material 92 will be directly formed on the roughened layer 61 when the transparent conductive layer 62 is omitted.

Preferably, the metal reflective layer 8 is subjected to a heat treatment under a working temperature ranging from 200 to 800° C., and more preferably, from 300 to 600° C. so as to permit atomic exchange through diffusion mechanism and to enhance adhesion strength between the metal reflective layer 8 and the transition layer 44. When the working temperature is less than 200° C., the extent of the atomic exchange is insufficient. When the working temperature is greater than 800° C., excessive atomic exchange occurs, which results in an adverse effect on the reflectively of the metal reflective layer 8.

Preferably, formation of the transition layer 44 is conducted using metal-organic chemical vapor deposition techniques with a II-containing source and a nitrogen-containing source as reactants under a working temperature ranging from 500 to 1200° C., and more preferably, from 600 to 1000° C. The II-containing source is selected from the group consisting of bis(cyclopentadienyl) magnesium, dimethylzinc, diethylzinc, and dimethylzinc:diethylzinc, and the nitrogen-containing source is selected from a mixture of hydrogen and nitrogen, ammonium, and combinations thereof.

Preferably, formation of the roughened layer 61 is conducted using metal-organic chemical vapor deposition techniques with a III-containing source and a nitrogen-containing source as reactants under a working temperature ranging from 500 to 1200° C. and a working pressure ranging from 76 to 760 Torr, and more preferably, under a working temperature ranging from 700 to 1000° C. and a working pressure ranging from 100 to 300 Torr. The III-containing source is selected from the group consisting of trimethylgallium (TMG), triethylgallium, triethylaluminum, and trimethylindium, and the nitrogen-containing source is selected from a mixture of hydrogen and nitrogen, ammonium, and combinations thereof. The roughened layer 61 is preferably doped with a II group element. Hence, when the transition layer 44 is made from Mg₃N₂, the roughened layer 61 is preferably made from Mg doped GaN.

The merits of the light emitting device of this invention will become apparent with reference to the following Example 1 and Comparative Examples 1 and 2.

### EXAMPLE 1

The light emitting device of Example 1 was prepared by the following steps.

The first semiconductor layer 41 of n-type GaN having a layer thickness of 3 μm, the active layer 42 of an InₓGaₗ₋ₓN/GaN multi-quantum well, and the second semiconductor layer 43 of Mg-doped p-type GaN having a layer thickness of 0.5 μm were successively formed on the sapphire substrate 3 in a MOCVD system under a working temperature of 1050° C. A nitrogen-containing source of a mixture of NH₃:H₂:N₂ (gas flow rate ratio=1:2:1) and a Mg-containing source of vaporized (C₅H₅)₂Mg carried by H₂ gas were introduced into the MOCVD system under a working temperature of 930° C. and a working pressure of 200 Torr so as to form the transition layer 44 having a layer thickness of 1 nm on the second semiconductor layer 43. The patterned mask material 91 of SiOₓ was then formed on the transition layer 44. A mixture of TMG:NH3 (gas flow rate ratio=1:320) together with vaporized (C₅H₅)₂Mg carried by H₂ gas was then introduced into the MOCVD system under a working temperature of 930° C. and a working pressure of 200 Torr so as to form the roughened layer 61 having a layer thickness of 1000 nm. The transparent conductive layer 62 of indium tin oxide (ITO) was then formed on the roughened layer 61 using e-beam evaporation techniques in the presence of O₂ gas. The patterned mask material 91 was then removed from the transition layer 44, followed by forming the etch mask material 92 on the transparent conductive layer 62. The semi-product thus formed was then subjected to dry etching so as to form the etched recess 40 and to define the electrode-forming region 411 of the first semiconductor layer 41. The etch mask material 92 was then removed, followed by forming the metal reflective layer 8 of Ti—Ag alloy having a layer thickness of about 20-50 nm on the transition layer 44 using e-beam evaporation techniques under a working temperature of 200° C. and heat treating the metal reflective layer 8 under a temperature of 450° C. The first and second electrodes 71, 72 were then formed on the electrode-forming region 411 of the first semiconductor layer 41 and the metal reflective layer 8, respectively.

### COMPARATIVE EXAMPLE 1

The light emitting device of Comparative Example 1 was prepared by steps similar to those of Example 1, except that the etch region 401 of the multi-layer structure 4 was covered by the roughened layer 61 instead of being covered by the patterned mask material 91.

Samples of the light emitting devices of Example 1 and Comparative Example 1 thus formed were subjected to current leakage test under an applied voltage of −5V. The test results show that the sample of Comparative Example 1 has a current leakage of 0.1 μA, while the sample of Example 1 has a current leakage of 0.03 μA which is far less than that of Comparative Example 1. Hence, by maintaining flatness of the etch region 401 of the multi-layer structure 4 to be etched therefrom prior to dry etching, the aforesaid formation of the undesired sidewall residuals as encountered in the prior art can be eliminated.

### COMPARATIVE EXAMPLE 2

The light emitting device of Comparative Example 2 was prepared by steps similar to those of Example 1, except that the transition layer 44 was omitted.

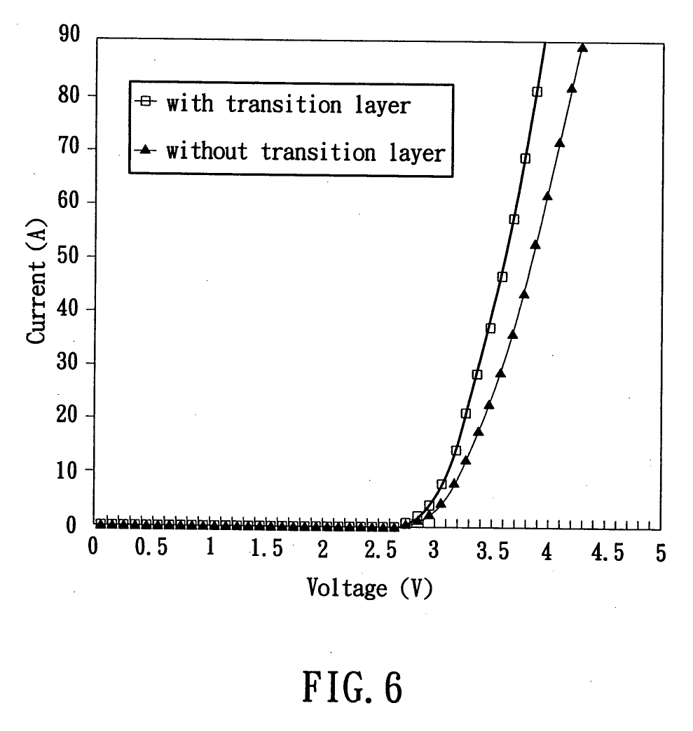

Samples of the light emitting devices of Example 1 and Comparative Example 2 thus formed were subjected to I-V characteristics test. As shown in FIG. 6, the test results show that the sample of Comparative Example 2 has a lower I-V curve slope than that of Example 1, which indicates a higher resistance and a lower effective current, which, in turn, indicates a higher energy gap between the second semiconductor layer 43 and the transparent conductive layer 62.

By forming the patterned mask material 91 on the transition layer 44 prior to the formation of the roughened layer 61 so as to obtain a flat region to be etched therefrom for subsequent dry etching of the layered structure according to the method of this invention, the aforesaid formation of the undesired sidewall residuals as encountered in the prior art can be eliminated.

While the present invention has been described in connection with what are considered the most practical and preferred embodiments, it is understood that this invention is not limited to the disclosed embodiments but is intended to cover various arrangements included within the spirit and scope of the broadest interpretation and equivalent arrangements.

What is claimed is:

1. A method for making a light emitting device, comprising:
(a) forming a multi-layer structure, which includes first and second semiconductor layers and an active layer disposed between the first and second semiconductor layers, on a substrate;
(b) forming a patterned mask material on one side of the multi-layer structure that is opposite to the substrate so as to cover an etch region of the multi-layer structure;
(c) forming a roughened layer on said one side of the multi-layer structure to cover an extraction region of the multi-layer structure;
(d) removing the patterned mask material from the multi-layer structure so as to expose the etch region of the multi-layer structure;
(e) forming an etch mask material on said roughened layer;
(f) dry etching the multi-layer structure at the exposed etch region so as to form an etched recess extending through the second semiconductor layer and the active layer and into the first semiconductor layer and so as to define an electrode-forming region on the first semiconductor layer that corresponds to the etch region of the multi-layer structure; and
(g) forming a first electrode on the electrode-forming region of the first semiconductor layer.

2. The method of claim 1, wherein in step (b) the patterned mask material further covers a connecting region of the multi-layer structure such that in step (c) the roughened layer formed on the extraction region surrounds a portion of the patterned mask material formed on the connecting region, and such that in step (d) an electrode-receiving hole is formed in the roughened layer when the portion of the patterned mask material formed on the connecting region is removed, thereby exposing the connecting region of the multi-layer structure after step (d), said method further comprising forming a second electrode on the connecting region of the multi-layer structure such that the second electrode extends outwardly through the electrode-receiving hole in the roughened layer after step (f).

3. The method of claim 2, wherein the roughened layer is made from a III-V compound, the multi-layer structure further including a transition layer formed on the second semiconductor layer and made from a II-V compound so that growth of the roughened layer on the transition layer is conducted through heterogeneous nucleation mechanism.

4. The method of claim 3, wherein the second semiconductor layer is made from a p-type GaN material, the transition layer having an energy gap ranging from 0.7 to 6.0 eV.

5. The method of claim 1, wherein in step (b) the patterned mask material further covers a connecting region of the multi-layer structure such that in step (c) the roughened layer formed on the extraction region surrounds a portion of the patterned mask material formed on the connecting region, and such that in step (d) an electrode-receiving hole is formed in the roughened layer when the portion of the patterned mask material formed on the connecting region is removed, thereby exposing the connecting region of the multi-layer structure after step (d), said method further comprising forming a metal reflective layer on the connecting region of the multi-layer structure such that the metal reflective layer is disposed in the electrode-receiving hole in the roughened layer, and a second electrode on the metal reflective layer such that the second electrode extends outwardly from the metal reflective layer through the electrode-receiving hole in the roughened layer after step (f).

6. The method of claim 5, further comprising subjecting the metal reflective layer to a heat treatment under a working temperature ranging from 200 to 800° C.

7. The method of claim 3, wherein II group element of the II-V compound of the transition layer is selected from the group consisting of Zn, Be, Mg, Ca, Sr, Ba, and Ra, and V group element of the II-V compound of the transition layer is selected from the group consisting of N, P, As, Sb, and Bi.

8. The method of claim 7, wherein the II-V compound of the transition layer has a formula of MgₓN_{y}, in which 1<x<3, and 1<y<3.

9. The method of claim 7, where information of the transition layer is conducted using metal-organic chemical vapor deposition techniques with a II-containing source and a nitrogen-containing source as reactants under a working temperature ranging from 500 to 1200° C.

10. The method of claim 9, wherein the II-containing source is selected from the group consisting of bis(cyclopentadienyl) magnesium, dimethylzinc, diethylzinc, and dimethylzinc:diethylzinc, and the nitrogen-containing source is selected from a mixture of hydrogen and nitrogen, ammonium, and combinations thereof.

11. The method of claim 3, wherein III group element of the III-V compound of the roughened layer is selected from the group consisting of B, Al, Ga, In, and Tl, and V group element of the III-V compound of the roughened layer is selected from the group consisting of N, P, As, Sb, and Bi.

12. The method of claim 11, wherein the III-V compound of the roughened layer is Mg doped GaN.

13. The method of claim 11, wherein formation of the roughened layer is conducted using metal-organic chemical vapor deposition techniques with a III-containing source and a nitrogen-containing source as reactants under a working temperature ranging from 500 to 1200° C. and a working pressure ranging from 76 to 760 Torr.

14. The method of claim 13, wherein the III-containing source is selected from the group consisting of trimethylgallium, triethylgallium, triethylaluminum, and trimethylindium, and the nitrogen-containing source is selected from a mixture of hydrogen and nitrogen, ammonium, and combinations thereof.

15. A light emitting device comprising:
a substrate;
a multi-layer structure formed on said substrate and including first and second semiconductor layers and an active layer sandwiched between said first and second semiconductor layers, said multi-layer structure being formed with an etched recess that extends through said second semiconductor layer and said active layer and into said first semiconductor layer so as to define an electrode-forming region on said first semiconductor layer;
a roughened layer formed on one side of said multi-layer structure that is opposite to said substrate, and formed with an electrode-receiving hole;
a first electrode formed on said electrode-forming region of said first semiconductor layer; and
a second electrode connected to said one side of said multi-layer structure and extending outwardly through said electrode-receiving hole;
wherein said electrode-forming region of said first semiconductor layer is defined by a process comprising
forming a patterned mask material on said one side of said multi-layer structure to cover an etch region of said multi-layer structure that corresponds to said electrode-forming region of said first semiconductor layer,
forming said roughened layer to cover an extraction region of said multi-layer structure,
removing said patterned mask material from said multi-layer structure so as to expose said etch region of said multi-layer structure,
forming an etch mask material on said roughened layer, and
dry etching said multi-layer structure at said exposed etch region so as to form said etched recess and so as to define said electrode-forming region of said first semiconductor layer.

16. The light emitting device of claim 15, wherein said roughened layer is made from a III-V compound, said multi-layer structure further including a transition layer formed on said second semiconductor layer and made from a II-V compound so that growth of said roughened layer on said transition layer is conducted through heterogeneous nucleation mechanism.

17. The light emitting device of claim 16, wherein said second semiconductor layer is made from a p-type GaN material, said transition layer having an energy gap ranging from 0.7 to 6.0 eV.

18. The light emitting device of claim 16, wherein II group element of said II-V compound of said transition layer is selected from the group consisting of Zn, Be, Mg, Ca, Sr, Ba, and Ra, and V group element of said II-V compound of said transition layer is selected from the group consisting of N, P, As, Sb, and Bi.

19. The light emitting device of claim 18, wherein III group element of said III-V compound of said roughened layer is selected from the group consisting of B, Al, Ga, In, and Tl, and V group element of said III-V compound of said roughened layer is selected from the group consisting of N, P, As, Sb, and Bi.

20. The light emitting device of claim 19, wherein said transition layer has a layer thickness ranging from 0.5 to 50 nm.

21. The light emitting device of claim 20, wherein said roughened layer has a layer thickness ranging from 50 to 3000 nm.

22. The light emitting device of claim 15, further comprising a metal reflective layer formed on said one side of said multi-layer structure and extending into said electrode-receiving hole in said roughened layer, said second electrode being formed on said metal reflective layer.

23. The light emitting device of claim 22, wherein said metal reflective layer is made from a metallic material selected from the group consisting of Ti, Al, Ag, Au, Cr, Pt, Cu, and combinations thereof.

24. The light emitting device of claim 22, wherein said metal reflective layer has a layer thickness ranging from 1 to 100 nm.
